(19) United States
(12) Patent Application Publication
(10) Pub. No.: US 2011/0235297 A1
(43) Pub. Date: Sep. 29, 2011

(54) Integrated circuit package component with lateral conductive pins

(75) Inventors: Hong-Bin Shi, Shanghai (CN); Jin-Chang Wu, Taipei County (TW)

(73) Assignees: Quanta Computer Inc., Taoyuan Shien (TW); Tech-Front (shanghai) Computer Co., Ltd., Shanghai (CN)

(21) Appl. No.: 12/805,486

(22) Filed: Aug. 3, 2010

(30) Foreign Application Priority Data
Mar. 29, 2010 (CN) 201010133908.1

(51) Int. Cl. H05K 7/00

(52) U.S. Cl. 361/783

(57) ABSTRACT

An integrated circuit package component with lateral conductive pins includes a package body having a middle conductive pin, an initial conductive pin and a final conductive pin. The middle conductive pin, the initial conductive pin and the final conductive pin are all disposed on a lateral side of the package body and respectively have a first soldering portion, a second soldering portion, and a third soldering portion, in which the middle conductive pin is arranged between the initial conductive pin and the final conductive pin, and an area of the middle conductive pin is smaller than that of the second soldering portion area and the third soldering portion in size.

### RELATED APPLICATIONS

This application claims priority to Chinese Application Serial Number 201010133908.1, Mar. 29, 2010, which is herein incorporated by reference.

### BACKGROUND

1. Technical Field

The present invention relates to an integrated circuit package component, more particularly to an integrated circuit package component with lateral conductive pins.

2. Description of Related Art

Integrated circuit package components are soldered on printed circuit boards through a plurality of conductive pins to form electrical and mechanical connections between the integrated circuit package component and the printed circuit board.

Due to different elasticity and coefficient of thermal expansion of the integrated circuit package component and the printed circuit board, when subject to mechanical or thermal stress, the warping levels of the integrated circuit package component and the printed circuit board are different, such conditions may result in conductive pins between the integrated circuit package component and the printed circuit board being broken or damaged.

For example, the widths of conductive pins provided on lateral sides of an integrated circuit package component of a conventional Quad Flat Package (QFP) are substantially the same.

Therefore, when the integrated circuit package component soldered on a printed circuit board is subject to a certain level of stress, breaks or deformation would be generated once the warping generated by the stress exceeds the endurance of the conductive pins, so that the electrical and mechanical (physical) connections provided by the conductive pins are no longer served. As such, signals are not able to transmit between the integrated circuit package component and the printed circuit board so as to direct failure.

In view of that, how to develop an integrated circuit package component capable of improving the described disadvantages and inconveniences shall be concerned.

### SUMMARY

One object of the present invention is to provide an integrated circuit package component with lateral conductive pins, to increase the tensile strength of lateral conductive pins of integrated circuit package components so as to lower the possibility of breaking due to bending generated when subject to a stress.

In one aspect of the present invention, the integrated circuit package component with lateral conductive pins is installed on a circuit board, and the integrated circuit package component includes a package body, a middle conductive pin, an initial conductive pin and a final conductive pin. The package body has a lateral side thereof. The middle conductive pin is disposed on the lateral side and has a first soldering portion with a first area for soldering on the circuit board. The initial conductive pin is disposed on the lateral side, and has a second soldering portion with a second area for soldering on the circuit board. The final conductive pin is disposed on the lateral side, and has a third soldering portion with a third area for soldering on the circuit board. Also, the middle conductive pin is arranged between the initial conductive pin and the final conductive pin, and the first area thereof is smaller than both the second area and the third area in size.

According to an embodiment of the present invention, areas of these conductive pins mentioned above gradually expand in a direction away from the middle conductive pin towards the initial conductive pin, or in another direction away from the middle conductive pin towards the final conductive pin.

In another aspect of the present invention, the integrated circuit package component with lateral conductive pins is installed on a circuit board, and the integrated circuit package component includes a package body, a first conductive pin group, a second conductive pin group and a third conductive pin group. The package body has a lateral side comprising a first section, a second section, and a third section in which the first section is positioned between the second section and the third section. The first conductive pin group comprises a plurality of first conductive pins arranged on the first section, and the first conductive pins respectively have a first soldering portion with a first area, in which the first areas are equal in size. The second conductive pin group comprises a plurality of second conductive pins arranged in the second section, and the second conductive pins respectively have a second soldering portion having a second area, in which the second areas are equal in size. The third conductive pin group comprises a plurality of third conductive pins arranged in the third section, and the third conductive pins respectively have a third soldering portion with a third area, in which the third areas are equal in size. Besides, each of the first areas is smaller than each of the second areas and each of the third areas in size.

Therefore, by adjusting the area sizes of the soldering portions of the lateral conductive pins of the integrated circuit package component of the present invention, the lateral conductive pins adjacent to a corner of the integrated circuit package component will have larger area in size for soldering comparing to those adjacent to a center line capable of equally separating the integrated circuit package component into two. Therefore, when the lateral conductive pins of the integrated circuit package component are soldered on the circuit board, the tensile strength of the lateral conductive pins of the integrated circuit package component is increased.

### BRIEF DESCRIPTION OF THE DRAWINGS

FIG. 1 is a distribution diagram of equal stress lines of an integrated circuit package component when being stressed.

FIG. 2A is a schematic view of a quad flat package (QFP) according to one embodiment of the integrated circuit package component with lateral conductive pins of the present invention.

FIG. 2B is a side view of the quad flat package (QFP) in FIG. 2A.

FIG. 3 is a bottom view of the quad flat package (QFP) in FIG. 2A.

FIG. 4 is a bottom view of a quad flat non-leaded package (QFN) according to another embodiment of the integrated circuit package component with lateral conductive pins of the present invention.

FIG. 5 is a bottom view of a small outline package (SOP) according to the other embodiment of the integrated circuit package component with lateral conductive pins of the present invention.

### DESCRIPTION OF THE PREFERRED EMBODIMENTS

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

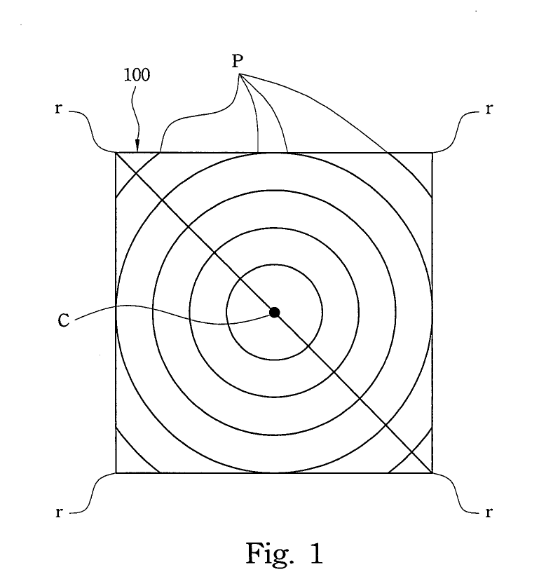

Refer to FIG. 1. FIG. 1 is a distribution diagram of equal stress lines of an integrated circuit package component when being stressed. After an integrated circuit package component 100 is soldered on a circuit board, the equal stress lines P are concentrically distributed from a geometric center c served as a circle center, towards the edge of the integrated circuit package component 100 when subject to a mechanical stress or thermal stress, i.e. the further away from the geometric center (c), the stronger the stress is applied. In other words, when the integrated circuit package component 100 is a rectangular shape, the corners (r) thereof are subject to the greatest stress.

In view of that, the present invention discloses an integrated circuit package component with lateral conductive pins. By adjusting the area sizes of the soldering portions of the lateral conductive pins of the integrated circuit package component of the present invention, the lateral conductive pins adjacent to a corner of the integrated circuit package component will have larger area in size for soldering comparing to those which are adjacent to the center of lateral sides of the integrated circuit package component. Therefore, when the lateral conductive pins of the integrated circuit package component are soldered on the circuit board, the tensile strength of the lateral conductive pins of the integrated circuit package component is increased.

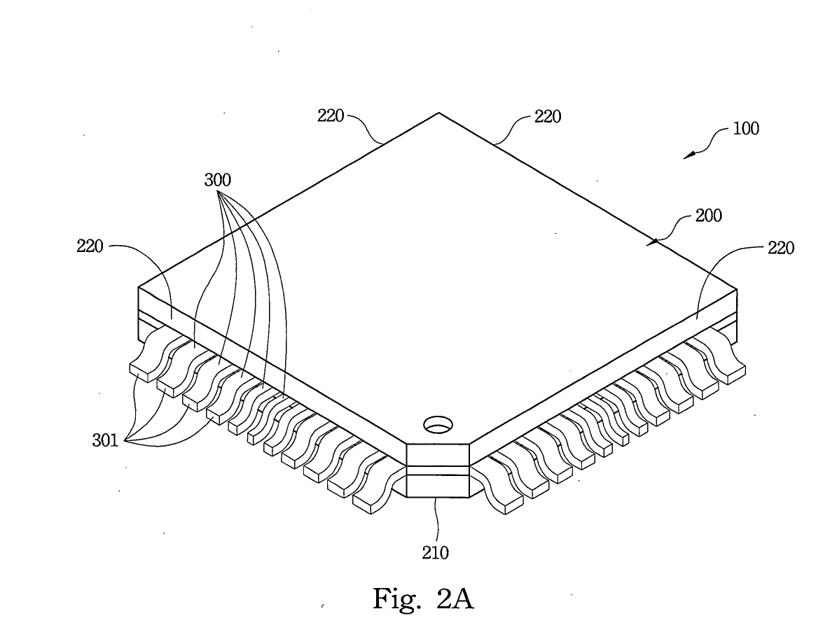

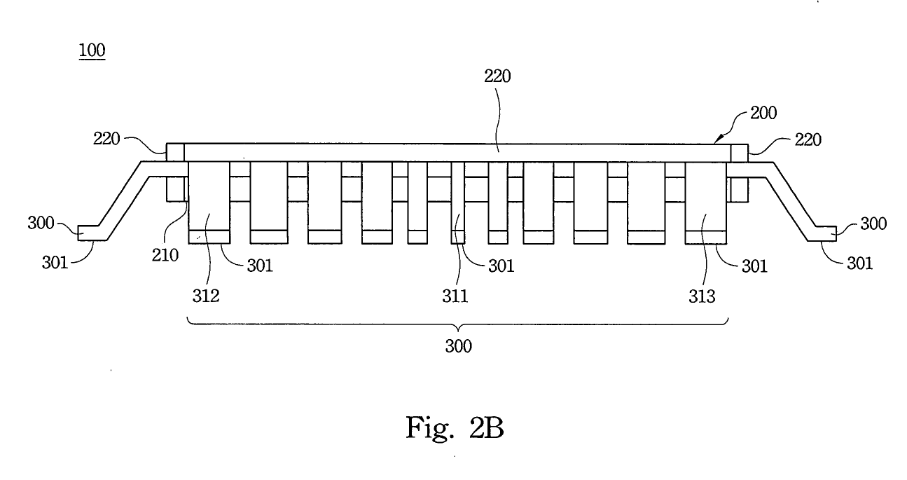

Refer to FIG. 2A and FIG. 2B, in which FIG. 2A is a schematic view of a quad flat package (QFP) according to one embodiment of the integrated circuit package component with lateral conductive pins of the present invention. FIG. 2B is a side view of the quad flat package (QFP) in FIG. 2A.

The integrated circuit package component 100 includes a package body 200 and a plurality of conductive pins 300. The package body 200 has an installing surface 210 and a plurality of lateral sides 220 surrounding and connecting the installing surface 210. The conductive pins 300 are linearly arranged on at least one lateral side 220. Specifically, for all of the conductive pins 300, one end of each conductive pin 300 is electronically disposed in the package body 200, the other end of each conductive pin 300 is extended outwards the package body 200 via the lateral sides 220 (FIG. 2B) or even, bent to attach the installing surface 210. Also, the other end of each conductive pin 300 has a soldering portion 301 for soldering on the circuit board.

Thus, when the integrated circuit package component 100 is installed on a circuit board (not shown), the installing surface 210 of the package body 200 faces the circuit board, and the soldering portions 301 of the conductive pins 300 soldered on the circuit board.

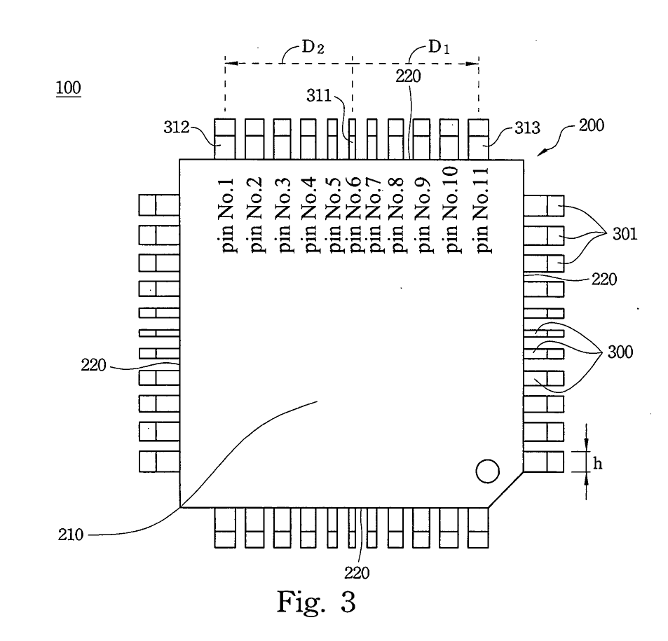

Refer to FIG. 3, in which FIG. 3 is a bottom view of the quad flat package (QFP) in FIG. 2A. In an embodiment of the present invention, the conductive pins 300, for example, at the lateral side 220, comprises a middle conductive pin 311 thereof defined as a median one of the conductive pins 300, an initial conductive pin 312 defined as an outermost one of the conductive pins 300, and an final conductive pin 313 defined as the other outermost one of the conductive pins 300 opposite to the initial conductive pin 312 in which the middle conductive pin 311 is arranged between the initial conductive pin 312 and the final conductive pin 313. Furthermore, the soldering portion 301 of the middle conductive pin 311 has a first area; the soldering portion 301 of the initial conductive pin 312 has a second area; the soldering portion 301 of the final conductive pin 313 has a third area, and both the second area and the third area are greater than the first area in size.

Therefore, since the initial conductive pin 312 and the final conductive pin 313 which are adjacent to the corner of the integrated circuit package component 100 have larger areas of the soldering portions 301 comparing to that of the soldering portion 301 of the middle conductive pin 311 adjacent to the center line capable of equally separating the integrated circuit package component 100 into two. Thus, the tensile strength of the integrated circuit package component 100 is higher.

Furthermore, the area variations of the soldering portions 301 of the conductive pins 300 in this embodiment can be gradually increased in sequence in a direction away from the middle conductive pin 311 towards the initial conductive pin 312, and in another direction away from the middle conductive pin 311 towards the final conductive pin 313.

A single middle conductive pin 311 would be defined among the conductive pins 300 if there are an odd number of conductive pins 300 at the lateral side 220. For example, if the integrated circuit package component 100 has eleven conductive pins 300 extended outwards each of the lateral sides 220, the eleven conductive pins 300 can be named in order as “pin No. 1”, “pin No. 2”, “pin No. 3”, “pin No. 4”, . . . , “pin No. 6”, . . . , and “pin No. 11” in which the pin No. 6 therefore is the middle conductive pin 311 of the conductive pins 300, and the pin No. 1 and the pin No. 11 therefore are the initial conductive pin 312 and the final conductive pin 313 of the conductive pins 300, respectively.

As shown in FIG. 3, the areas of the soldering portions 301 of the conductive pins 300 can be gradually expanded in sequence in a direction D1 away from the “pin No. 6” towards the “pin No. 11”, and in another direction D2 away from the “pin No. 6” towards the “pin No. 1”.

Specifically, a width “h” of the first area of the soldering portion 301 of the middle conductive pin 311 (e.g. pin No. 6), for example, can be anyone in a range of 0.22 mm-0.32 mm, that is 0.22, 0.23, 0.24, 0.25, 0.26, 0.27, 0.28, 0.29, 0.30, 0.31 or 0.32. A width “h” of the second area of the soldering portion 301 of the initial conductive pin 312 (e.g. pin No. 1), for example, can be anyone in a range of 0.28 mm-0.38 mm, that is 0.28, 0.29, 0.30, 0.31, 0.32, 0.33, 0.34, 0.35, 0.36, 0.37 or 0.38. A width “h” of the third area of the soldering portion 301 of the final conductive pin 313 (e.g. pin No. 11), for example, can be anyone in a range of 0.28 mm-0.38 mm, that is 0.28, 0.29, 0.30, 0.31, 0.32, 0.33, 0.34, 0.35, 0.36, 0.37, or 0.38.

On the other hand, if the quantity of the conductive pins 300 is an even number, two middle conductive pins 311 would be defined among the conductive pins 300. The area variations of the soldering portions 301 of the conductive pins 300 still can be gradually increased in sequence following a direction away from one of the middle conductive pins 311 towards the initial conductive pin 312, and another direction away from the other one of the middle conductive pins 311 towards the final conductive pin 313. An embodiment that the quantity of the conductive pins 300 is an even number will be illustrated as follows.

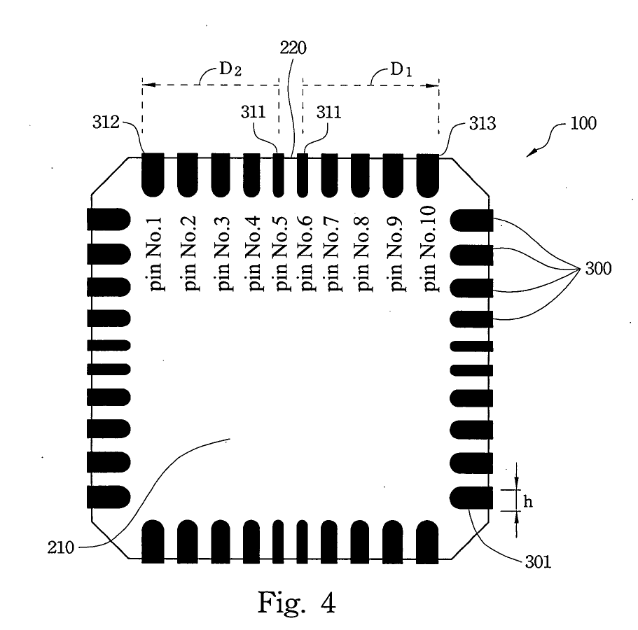

Refer to FIG. 4 in which FIG. 4 is a bottom view of a quad flat non-leaded package (QFN) according to another embodiment of the integrated circuit package component with lateral conductive pins of the present invention. For example, when the integrated circuit package component 100 has ten conductive pins 300 extended outwards the lateral sides 220, and the conductive pins 300 can be named in order as “pin No. 1”, “pin No. 2”, “pin No. 3”, “pin No. 4”, . . . , “pin No. 5”, “pin No. 6” . . . , and “pin No. 10” in which the pin No. 5 and “pin No. 6” therefore respectively are the middle conductive pins 311 of the conductive pins 300, and the “pin No. 1” and the “pin No. 10” therefore are the initial conductive pin 312 and the final conductive pin 313 of the conductive pins 300, respectively.

As shown in FIG. 4, the areas of the soldering portions 301 of the conductive pins 300 can be gradually expanded in sequence in a direction D1 away from the “pin No. 6” towards the “pin No. 10”, and another direction D2 away from the “pin No. 5” towards the “pin No. 1”.

Specifically, a width “h” of the soldering portion 301 of each middle conductive pins 311 (e.g. pin No. 5 or pin No. 6), for example, can be anyone in a range of 0.22 mm-0.32 mm, that is 0.22, 0.23, 0.24, 0.25, 0.26, 0.27, 0.28, 0.29, 0.30, 0.31 or 0.32. A width “h” of the soldering portion 301 of the initial conductive pin 312 (e.g. pin No. 1), for example, can be anyone in a range of 0.28 mm-0.38 mm, that is 0.28, 0.29, 0.30, 0.31, 0.32, 0.33, 0.34, 0.35, 0.36, 0.37 or 0.38. A width “h” of the soldering portion 301 of the final conductive pin 313 (e.g. pin No. 10), for example, can be anyone in a range of 0.28 mm-0.38 mm, that is 0.28, 0.29, 0.30, 0.31, 0.32, 0.33, 0.34, 0.35, 0.36, 0.37, or 0.38.

Normally, the conductive pins 300 can be formed in a pin shape, a piece shape or a block shape. Since the conductive pins 300 are equal in length and thickness, thus, width “h” can be a varied parameter in determination of the areas of the soldering portion 301 of the conductive pins 300. Thus, different width “h” will determine different area of the soldering portion 301 of the conductive pins 300 in size.

However, the soldering portion 301 of the initial conductive pins 312 and the soldering portion 301 of the final conductive pins 313 are not limited to be equal or unequal in size as long as the soldering portion 301 of the initial conductive pins 312 and t the soldering portion 301 of the final conductive pins 313 are greater than that of the middle conductive pin 311, so as to provide a better tensile strength of the lateral conductive pins for the integrated circuit package component 100.

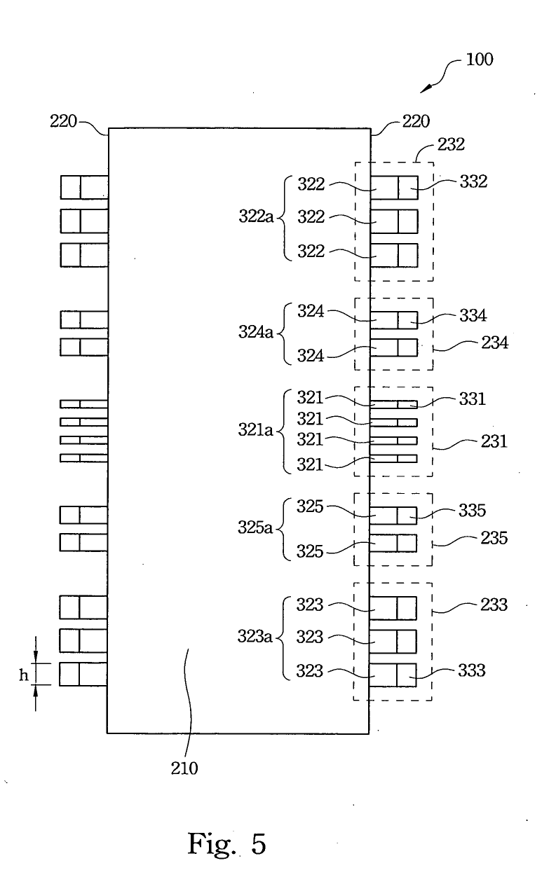

Refer to FIG. 5 in which FIG. 5 is a bottom view of a small outline package (SOP) according to the other embodiment of the integrated circuit package component with lateral conductive pins of the present invention.

In another embodiment of the present invention, a first section 231, a second section 232, and a third section 233 are defined on the lateral sides 220 in which the first section 231 is positioned between the second section 232 and the third section 233.

The conductive pins 300 comprises a plurality of first conductive pins 321 classified as a first conductive pin group 321a, a plurality of second conductive pins 322 classified as a second conductive pin group 322a, and a plurality of third conductive pins 323 classified as a third conductive pin group 323a. The first conductive pins 321 are linearly arranged on the first section 231 of the lateral side 220; the second conductive pins 322 are linearly arranged on the second section 232 of the lateral side 220; the third conductive pins 322 are linearly arranged on the third section 232 of the lateral side 220.

Each of the first conductive pins 321 respectively has a first soldering portion 331 with a first area, in which the first areas of the first conductive pins 321 are equal in size; each of the second conductive pins 322 has a second soldering portion 332 having a second area, in which the second areas of the second conductive pins 322 are equal in size; each of the third conductive pins 323 has a third soldering portion 333 with a third area, in which the third areas of the third conductive pins are equal in size. Each of the first areas of the first soldering portion 331 is smaller than each of the second areas of the second soldering portion 332 and each of the third areas of the third soldering portion 333 in size.

Since the second areas of the second soldering portions 332 and the third areas of the third soldering portions 333 are greater than the first areas of the first soldering portions 331, the conductive pins 322, 323 adjacent to the corner of the integrated circuit package component 100 have larger areas for soldering comparing to those adjacent to the center line of the integrated circuit package component 100, so as to provide a better tensile strength of the lateral conductive pins for the integrated circuit package component 100.

Specifically, a width “h” of the first area of each first soldering portions 331, for example, can be anywhere in the range between 0.22 mm and 0.32 mm, that is 0.22, 0.23, 0.24, 0.25, 0.26, 0.27, 0.28; 0.29, 0.30, 0.31 or 0.32. A width “h” of the second area of each second soldering portions 332, for example, can be anyone in a range of 0.28 mm-0.38 mm, that is 0.28, 0.29, 0.30, 0.31, 0.32, 0.33, 0.34, 0.35, 0.36, 0.37 or 0.38. A width “h” of the third area of each third soldering portions 333, for example, can be anyone in a range of 0.28 mm-0.38 mm, that is 0.28, 0.29, 0.30, 0.31, 0.32, 0.33, 0.34, 0.35, 0.36, 0.37, or 0.38.

Normally, the conductive pins 300 are formed in a pin shape, a piece shape or a block shape. Since the conductive pins 300 are all equal in length and thickness, width “h” can be a varied parameter in determination of the areas of the soldering portions of the conductive pins 300. Thus, different width “h” will determine different area of the soldering portion 331, 332, 333 of the conductive pins 300 in size.

In this embodiment of the present invention, each of the lateral sides 220 of the package body 200 further is defined a fourth section 234 positioned between the first section 231 and the second section 232, and a fifth section 235 positioned between the first section 231 and the third section 233.

The conductive pins 300 further comprises a plurality of fourth conductive pins 324 classified as a fourth conductive pin group 324a and a plurality of fifth conductive pins 325 classified as a fifth conductive pin group 325a. The fourth conductive pins 324 are linearly arranged on the fourth section 234 of the lateral side 220; the fifth conductive pins 325 are linearly arranged on the fifth section 235 of the lateral side 220.

Each of the fourth conductive pins 324 has a fourth soldering portion 334 with a fourth area, in which the fourth areas are equal. Each fourth area of the fourth soldering portions 334 is larger than that of the first soldering portions 331, but smaller than that of the second soldering portions 332.

Each of the fifth conductive pins 325 has a fifth soldering portion 335 with a fifth area, in which the fifth areas are equal. Each fifth area of the fifth soldering portions 335 is larger than that of the first soldering portions 331, but smaller than that of the third soldering portions 333.

According to the embodiments described above, the integrated circuit package component 100 not limited in appearance, type or format as long as the integrated circuit package component having lateral pins extending outwards a lateral side thereof meets the technical characteristics of the present invention mentioned above.

Furthermore, in a specific embodiment of the present invention, the package body 200 of the integrated circuit package component 100 can be formed as a rectangular shape, a round shape or a polygon shape. As the package body 200 of the integrated circuit package component 100 is in a round shape, the conductive pins 300 are arranged around a periphery rim thereof. As the package body 200 of the integrated circuit package component 100 is in a rectangular shape, the conductive pins 300 can be linearly arranged on at least two opposite lateral sides thereof or all of the four lateral sides thereof, rather than limited on a single one lateral side thereof only.

Also, in another specific embodiment of the present invention, the integrated circuit package component 100, for example, can be a quad flat package (QFP), a quad flat non-leaded package (QFN) or a quad flat I-leaded package (QFI); the integrated circuit package component 100, for example, also can be a small outline package (SOP), a small outline J-lead package (SOJ) or a small outline I-lead package (SOI); the integrated circuit package component 100, for example, also can be a ceramic leaded chip carrier (CLCC), a plastic leaded chip carrier (PLCC) or a J-leaded chip carrier (JLCC); the integrated circuit package component 100, for example, also can be a single in-line package (SIP), a dual in-line package (DIP) or a zigzag in-line package (ZIP).

Needed to be indicated is that the first section 231 to fifth section 235 mentioned above in the specification are only named for conveniently illustrating the relative positions of the first conductive pins 321 to the fifth conductive pins 325. One skilled in the related fields of the present invention may recognize the first section 231 to fifth section 235 by identifying different area sizes of the soldering portions of the different conductive pins in the different sections.

Moreover, the first conductive pins 321, the second conductive pins 322, the third conductive pins 323, the fourth conductive pins 324 and the fifth conductive pins 325 mentioned above in the specification are some of the conductive pins 300. The “pin No. 1” to “pin No. 11” or “pin No. 1” to “pin No. 10” mentioned above in the specification are some of the conductive pins 300 as well. Also, the first conductive pin group 321a to the fifth conductive pin group 325a mentioned above in the specification are only named for conveniently distinguishing the conductive pins in the corresponding conductive pin group. One skilled in the related fields of the present invention may recognize the first conductive pin group 321a to the fifth conductive pin group 325a by identifying different area sizes of the soldering portions of the different conductive pins of the corresponding group.

Accordingly, with the feature of concentric distribution of stress for integrated circuit package component, the present invention has provided the mentioned features for reinforcing enhancing the tensile strength of these lateral pins. Thus the structural strength of integrated circuit package component installed on a printed circuit board is enhanced, so as to increase the anti-fatigue capability and reliability of the integrated circuit package component, and the size of integrated circuit package component is also reduced.

The reader's attention is directed to all papers and documents which are filed concurrently with his specification and which are open to public inspection with this specification, and the contents of all such papers and documents are incorporated herein by reference.

All the features disclosed in this specification (including any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

What is claimed is:

1. An integrated circuit package component with lateral conductive pins, for being installed on a circuit board, the integrated circuit package component comprising:
a package body having a lateral side thereof;
a middle conductive pin disposed on the lateral side and having a first soldering portion with a first area for soldering on the circuit board,
an initial conductive pin disposed on the lateral side, and having a second soldering portion with a second area for soldering on the circuit board; and
a final conductive pin disposed on the lateral side, and having a third soldering portion with a third area for soldering on the circuit board,
wherein the middle conductive pin is arranged between the initial conductive pin and the final conductive pin, and the first area is smaller than the second area and the third area.

2. The integrated circuit package component with lateral conductive pins according to claim 1 further comprising:
a plurality of first conductive pins arranged between the initial conductive pin and the middle conductive pin, and respectively having a fourth soldering portion with a fourth area for soldering on the circuit board; and
a plurality of second conductive pins arranged between the final conductive pin and the middle conductive pin, and respectively having a fifth soldering portion with a fifth area for soldering on the circuit board,
wherein the fourth areas are gradually expanded in sequence in a direction away from the middle conductive pin towards the initial conductive pin, and the fifth areas are gradually expanded in sequence in another direction away from the middle conductive pin towards the final conductive pin.

3. The integrated circuit package component with lateral conductive pins according to claim 1, wherein a width of the first area is in a range from 0.22 mm to 0.32 mm.

4. The integrated circuit package component with lateral conductive pins according to claim 1, wherein a width of the second area or the third area is in a range from 0.28 to 0.38 mm.

5. The integrated circuit package component with lateral conductive pins according to claim 1, wherein the second area and the third area are equal in size.

6. The integrated circuit package component with lateral conductive pins according to claim 1, wherein the second area and the third area are unequal in size.

7. The integrated circuit package component with lateral conductive pins according to claim 1, wherein the package body is formed in a rectangular shape or a round shape.

8. The integrated circuit package component with lateral conductive pins according to claim 1, wherein the integrated circuit package component is a quad flat package (QFP), a quad flat non-leaded package (QFN) or a quad flat I-leaded package (QFI).

9. The integrated circuit package component with lateral conductive pins according to claim 1, wherein the integrated circuit package component is a small outline package (SOP), a small outline J-lead package (SOJ) or a small outline I-lead package (SOI).

10. The integrated circuit package component with lateral conductive pins according to claim 1, wherein the integrated circuit package component is a ceramic leaded chip carrier (CLCC), a plastic leaded chip carrier (PLCC) or a J-leaded chip carrier (JLCC).

11. The integrated circuit package component with lateral conductive pins according to claim 1, wherein the integrated circuit package component is a single in-line package (SIP), a dual in-line package (DIP) or a zigzag in-line package (ZIP).

12. An integrated circuit package component with lateral conductive pins, for being installed on a circuit board, the integrated circuit package component comprising:
a package body having a lateral side comprising a first section, a second section, and a third section, wherein the first section is positioned between the second section and the third section;
a first conductive pin group comprising a plurality of first conductive pins arranged on the first section, and the first conductive pins respectively having a first soldering portion with a first area, wherein the first areas are equal in size;
a second conductive pin group comprising a plurality of second conductive pins arranged on the second section, and the second conductive pins respectively having a second soldering portion with a second area, wherein the second areas are equal in size;
a third conductive pin group comprising a plurality of third conductive pins arranged on the third section, and the third conductive pins respectively having a third soldering portion with a third area, wherein the third areas are equal in size,
wherein each of the first areas is smaller than each of the second areas and each of the third areas.

13. The integrated circuit package component with lateral conductive pins according to claim 12, wherein a width of each first area is in a range from 0.22 to 0.32 mm.

14. The integrated circuit package component with lateral conductive pins according to claim 12, wherein a width of each second area or each third area is in a range from 0.28 to 0.38 mm.

15. The integrated circuit package component with lateral conductive pins according to claim 12, wherein the integrated circuit package component is a quad flat package (QFP), a quad flat non-leaded package (QFN), a quad flat I-leaded package (QFI), a small outline package (SOP), a small outline J-lead package (SOJ) or a small outline I-lead package (SOI).

16. The integrated circuit package component with lateral conductive pins according to claim 12, wherein the integrated circuit package component is a ceramic leaded chip carrier (CLCC), a plastic leaded chip carrier (PLCC) or a J-leaded chip carrier (JLCC).

17. The integrated circuit package component with lateral conductive pins according to claim 12, wherein the integrated circuit package component is a single in-line package (SIP), a dual in-line package (DIP) or a zigzag in-line package (ZIP).
